(19) United States
(12) Patent Application Publication
(10) Pub. No.: US 2005/0224925 A1
(43) Pub. Date: Oct. 13, 2005

(54) Lead frame having a tilt flap for locking molding compound and semiconductor device having the same

(76) Inventors: Peter Chou, Taipei (TW); Cindy Ding, Tianjin (TW); Anne Hao, Tianjin (TW)

Correspondence Address: MAYER, FORTKORT & WILLIAMS, PC, 251 NORTH AVENUE WEST, 2ND FLOOR, WESTFIELD, NJ, 07090, US

(21) Appl. No.: 10/815,499

(22) Filed: Apr. 1, 2004

(51) Int. Cl. H01L 23/495

(52) U.S. Cl. 257/666

(57) ABSTRACT

To enhance the adhesion force between a lead frame and a molding compound of a surface mount semiconductor device, a lead frame having two opposite sides, with at least one tilt flap for locking a molding compound extending from one side and a reduced portion of the lead frame extending from the opposite side, and a surface mount semiconductor device having the same, are disclosed. The at least one tilt flap and the reduced portion are formed on the lead frame such that the adhesion force between the lead frame and the molding compound is enhanced.

### BACKGROUND OF THE INVENTION

1. Field of the Invention

The present invention generally relates to a semiconductor device, and more particularly to a surface mount semiconductor device.

2. Description of the Related Art

The adhesion between a molding compound and a lead frame is a very important issue for a surface mount device. If the adhesion strength between the molding compound and the lead frame is not strong enough, the molding compound will be easily separated from the lead frame and the reliability of the device will be thus deteriorated.

There are many ways to increase the adhesion strength between the molding compound and the lead frame. FIGS. 1(a) and 1(b) illustrate conventional locking-hole designs for a lead frame. In FIGS. 1(a) and 1(b), locking holes (11, 12) are formed in the lead frame (10) for increasing the adhesion strength between the molding compound and the lead frame (10). However, such a design can only be applied to a lead frame having a thickness of more than 10 mils. If the thickness of the lead frame is less than 10 mils, the locking holes cannot effectively increase the adhesion strength between the molding compound and the lead frame.

FIG. 2 illustrates another conventional taper edge design for a lead frame. In FIG. 2, taper edges (21) are formed at the edges of the lead frame (20) for increasing the adhesion strength between the molding compound (22) and the lead frame (20). Although the taper edges can be formed by a stamping process, the stamping process can only be applied to a lead frame having a thickness of more than 10 mils. If the thickness of the lead frame is less than 10 mils, the taper edges have to be formed by an etching method. However, the cost for etching the taper edges is very high.

FIG. 3 illustrates a conventional locking hook design for a lead frame. In FIG. 3, a large locking hook (34) is formed on the lead frame (30) and a die (33) is attached thereon. Although the large locking hook (34) can effectively increase the adhesion strength between the molding compound (32) and the lead frame (30), it takes a large portion of the lead frame (30) to form the locking hook (34) and thus the lead frame material is wasted, rendering the high cost. In addition, the space for a die is also reduced and thus the electrical capacity of the die is limited.

### SUMMARY OF THE INVENTION

A lead frame having at least one tilt flap for locking molding compound and a surface mount semiconductor device having the same are disclosed, wherein at least one tilt flap is formed on the lead frame such that the adhesion force between the lead frame and the molding compound is enhanced without wasting much lead frame material. In addition, the space for a die and the electrical capacity of the die are increased.

Preferably, the lead frame comprises a first edge and a second edge, the second edge has a reduced portion extending outward from the lead frame. The at least one tilt flap is provided at the first edge and extended outward from the lead frame and the second edge of the lead frame further comprises at least one tilt flap extending inward towards the lead frame.

### BRIEF DESCRIPTION OF THE DRAWINGS

For a more complete understanding of the present invention and the advantages thereof, reference is now made to the following descriptions, taken in conjunction with the accompanying drawings which illustrate the embodiments of the present invention, wherein:

FIGS. 1(a) and (b) illustrate conventional locking-hole designs for a lead frame;

FIG. 2 illustrates a conventional taper edge design for a lead frame;

FIG. 3 illustrates a conventional locking hook design for a lead frame;

FIG. 4 illustrates a surface mount semiconductor device of the present invention;

FIG. 5 illustrates an embodiment of a die-attached portion of a lead frame of the present invention;

FIG. 6(a)-6(c) illustrate different embodiments of the lead frame of the present invention;

FIG. 7 is a schematic diagram for measuring the adhesion forces of the embodiments of the present invention; and

FIG. 8 is a table illustrating measured results of the embodiments of the present invention.

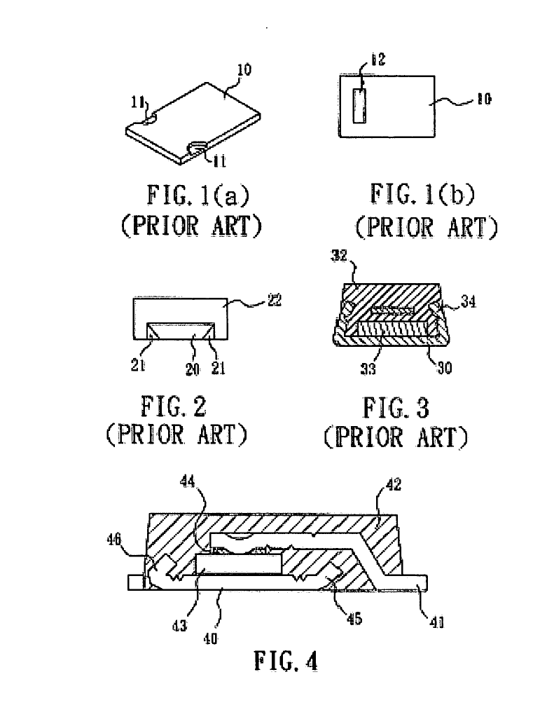

### DETAILED DESCRIPTION OF THE PREFERRED EMBODIMENTS

FIG. 4 illustrates a cross-sectional view of a surface mount semiconductor device, such as a rectifier, in accordance with the present invention. The semiconductor device includes a bottom lead frame (40), wherein the thickness of the bottom lead frame (40) is preferably less than 10 mils and has at least one tilt flap or a hook (45); a die (43) is attached on the bottom lead frame (40); a top conductive finger or wire (41) is attached on the die (43) by a conductive material (44), such as solder; and a molding compound (42) is provided for molding the semiconductor device, wherein the molding compound (42) surrounds the at least one tilt flap (45) to thereby increase the adhesion strength between the molding compound and the lead frame and to “lock” the two together. Preferably, the bottom lead frame (40) comprises a first edge and a second edge, the second edge including a “reduced portion” (described further below). The at least one tilt flap 45 extends outward from the bottom lead frame (40) and is provided at the first edge and extends outward from the bottom lead frame (40). The second edge of the bottom lead frame (40) includes at least one tilt flap (46), and preferably two tilt flaps, extending inward toward the bottom lead frame (40).

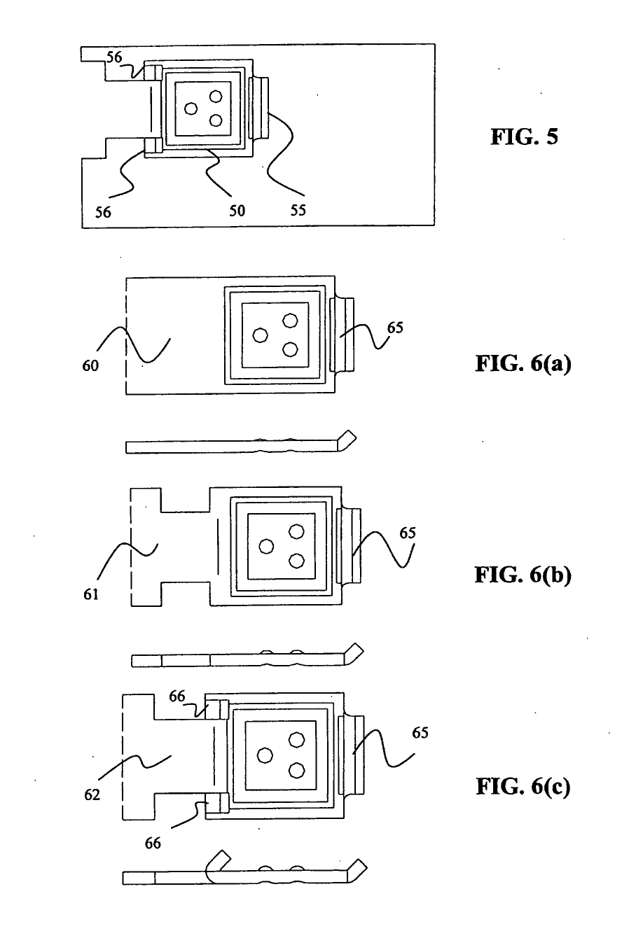

FIG. 5 illustrates one embodiment of a top view of a die-attached portion of a lead frame according to the present invention. The lead frame can be used in the semiconductor device as shown in FIG. 4. The lead frame is provided with at least one tilt flap or hook (55) for locking a molding compound. The die-attached portion (50) of the lead frame has a first edge and a second edge. In the embodiment illustrated, the second edge has a reduced portion (i.e., a portion of the lead frame eliminated from the width of the lead frame extending outward from the die-attached portion (50)) and two tilt flaps (56). The at least one tilt flap (55) is provided at the first edge and extended outward from the side-attached portion (50). The second edge of the die-attached portion (50) includes at least one tilt flap (56), and preferably two tilt flaps, extending inward to the side-attached portion (50).

FIGS. 6(a)-6(c) illustrate top views and corresponding side views of additional embodiments of a lead frame according to the present invention. FIG. 6(a) refers to a lead frame (60) having a tilt flap (65) at its first side without a reduced portion at its second side. FIG. 6(b) refers to a lead frame (60) having a tilt flap (65) at its first side with a reduced portion (61) at its opposite second side. FIG. 6(c) refers to a lead frame (60) having a tilt flap (65) at its first side with a reduced portion (62) and two tilt flaps (66) at its second side.

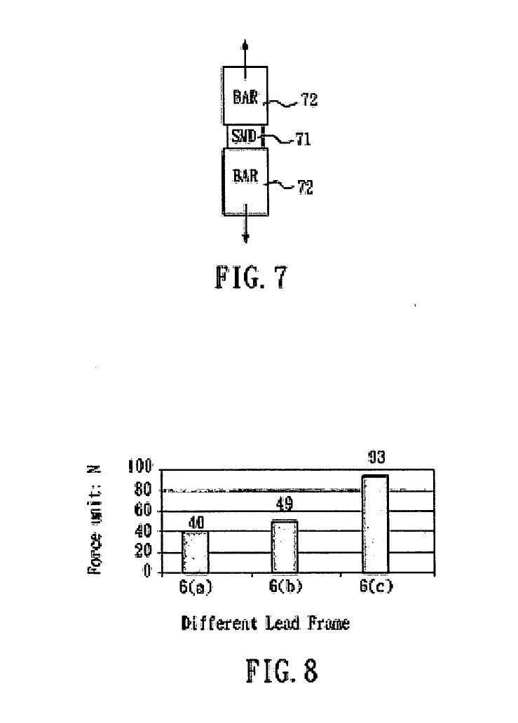

FIG. 7 is a schematic diagram for measuring the adhesion forces of the embodiments shown in FIGS. 6(a)-6(c). The tensile strength of the surface mount device (SMD) (71) can be obtained by pulling the bars (72). The measured results are shown in FIG. 8. It is known from FIG. 8 that the embodiments of a lead frame according to the present invention as shown in FIGS. 6(a)-6(c), and particularly in FIG. 6(c), have significantly enhanced the adhesion force between the lead frame and the molding compound without wasting much lead frame material. In addition, the space for the die and the electrical capacity of the die are increased.

Although the present invention and its advantage have been described in detail, it should be understood that various changes, substitutions and alternations can be made herein without departing from the spirit and scope of the invention as defined by the appended claims.

1. A semiconductor device, comprising
a bottom lead frame having at least one tilt flap;
a die attached on the bottom lead frame;
a top conductive element attached on the die; and
a molding compound for molding the semiconductor device, wherein the molding compound surrounds the at least one tilt flap to lock the molding compound onto said bottom lead frame.

2. The semiconductor device of claim 1, wherein the bottom lead frame has a first edge and a second edge, the first edge opposite the second edge, and the second edge of the bottom lead frame having a reduced portion extending outward from the die-attached portion of the bottom lead frame, wherein the reduced portion has a portion of the bottom lead frame removed from each of opposite sides thereof.

3. The semiconductor device of claim 2, wherein the at least one tilt flap is provided at the first edge and extends outward from the bottom lead frame.

4. The semiconductor device of claim 2, wherein the second edge of the bottom lead frame further comprises at least one tilt flap extending inward towards the bottom lead frame.

5. The semiconductor device of claim 3, wherein the second edge of the bottom lead frame further comprises at least one tilt flap extending inward towards the bottom lead frame.

6. The semiconductor device of claim 1, wherein the semiconductor device is a rectifier of surface mount package.

7. The semiconductor device of claim 1, wherein the thickness of the bottom lead frame is less than 10 mils.

8. The semiconductor device of claim 4, wherein the second edge includes two tilt flaps extending inwards towards the bottom lead frame.

9. The semiconductor device of claim 5, wherein the second edge includes two tilt flaps extending inwards towards the bottom lead frame.

10. A lead frame for a semiconductor device, comprising
a die-attached portion having a first edge and an opposite second edge, the first edge having at least one tilt flap, and
the second edge having a reduced portion extending outward from the die-attached portion.

11. The lead frame of claim 10, wherein the at least one tilt flap extends outward from the die-attached portion.

12. The lead frame of claim 10, wherein the second edge of the die-attached portion further comprises at least one tilt flap extending inward to the die-attached portion.

13. The lead frame of claim 11, wherein the second edge of the die-attached portion further comprises at least one tilt flap extending inward to the die-attached portion.

14. The lead frame of claim 12, wherein two tilt flaps extend inwards towards the die-attached portion.

15. The lead frame of claim 13, wherein two tilt flaps extend inward towards the die-attached portion.

16. The lead frame of claim 14, wherein each of the two tilt flaps extend upwards from the reduced portion

17. The lead frame of claim 15, wherein each of the two tilt flaps extend upwards from the reduced portion

18. The lead frame of claim 10, wherein the thickness of the lead frame is less than 10 mils.
